(19) United States
(12) Patent Application Publication
(10) Pub. No.: US 2026/0005139 A1
(43) Pub. Date: Jan. 1, 2026

(54) STRUCTURES WITH ENHANCED THERMAL HEAT SPREADING AND REMOVAL

(71) Applicant: International Business Machines Corporation, Armonk, NY (US)

(72) Inventors: John Knickerbocker, Monroe, NY (US); John W Golz, Hopewell Junction, NY (US); Keiji Matsumoto, Yokohama-shi (JP); Mukta Ghate Farooq, Hopewell Junction, NY (US)

(21) Appl. No.: 18/756,739

(22) Filed: Jun. 27, 2024

(51) Int. Cl. H01L 23/528; H01L 23/367; H01L 23/522; H01L 25/065

(52) U.S. Cl. CPC H01L 23/5283; H01L 23/3675; H01L 23/5226; H01L 23/5286; H01L 25/0657; H01L 2225/06541

(57) ABSTRACT

Structures including semiconductor chips (including chiplets and stacked chips/chiplets) are provided in which thermal heat removal is enhanced. The enhanced thermal heat removal is provided by utilizing interlayer dielectric (ILD) materials in at least one of the frontside back-end-of-the-line (BEOL) structure or the backside BEOL structure that have a high thermal conductivity.

### BACKGROUND

The present application relates to semiconductor technology, and more particularly to structures including semiconductor chips (including chiplets and stacked chips/chiplets) and/or advanced packages that have enhanced thermal heat spreading and thermal heat removal.

In the semiconductor industry, the removal of heat from semiconductor devices and systems continues to remain a technology challenge that can often limit performance and reliability. Heat generated during the operation of the semiconductor device needs to be efficiently removed in order to minimize the rise in the temperature of the semiconductor chip. A variety of thermal management techniques have been used ranging from passive cooling for lower power chips, to air cooling facilitated by heat sinks for medium power chips and to liquid cooling or two phase cooling for high power chips.

The thermal management challenge has been exacerbated by recent advances in heterogeneous integration in chip and packaging level architecture. For example, bonding of multiple dies to produce three-dimensional integrated circuits offers several important electrical benefits, contributing towards continuation of Moore's law, but also leads to significant thermal contact resistance between dies, which may increase the total temperature rise in the chip(s). The use of dis-similar materials in different dies (heterogeneous integration, such as memory-on-logic chips) or within a single or stacked types of die(s) or chip(s) or chiplet(s), such as, but not limited to, stacked memory chiplets or logic chiplets, due to the use of through-silicon vias (TSVs) also presents thermal management challenges.

### SUMMARY

Structures including semiconductor chips (including chiplets and stacked chips/chiplets) and/or advanced packages technologies are provided in which thermal heat spreading and thermal heat removal is enhanced. The enhanced thermal heat spreading and thermal heat removal is provided by utilizing an interlayer dielectric (ILD) material in at least one of the frontside back-end-of-the-line (BEOL) structure or the backside BEOL structure that has a high thermal conductivity. In some embodiments, additional metal vias beyond that which is required for typical signal and/or power delivery can be used to transport heat through the structure. In some embodiments, through vias can be inserted in at least one of the frontside BEOL structure or the backside BEOL to further enhance heat transport through the structure. In yet some embodiments, high thermal conductive conductors can be used in at least one of the chips' frontside BEOL structure or the chips' backside BEOL structure or in the advanced package.

In one embodiment of the present application, a structure is provided that includes a front-end-of-the-line (FEOL) level including at least one semiconductor device and having a frontside and a backside, a frontside BEOL structure located on the frontside of the FEOL level, and a backside BEOL structure located on the frontside of the FEOL level, in which at least one of the frontside BEOL structure or the backside BEOL structure includes an ILD material having a thermal conductivity of greater than 0.5 W/mK (in which W is watts, m is meter and K is Kelvin) up to 2000 W/mK (when compared to a semiconductor traditional SiO₂ and SiN dielectric materials and compared to organic dielectric materials used in organic laminate substrates and interposers).

In another embodiment of the present application, a chip stack containing semiconductor structure is provided that includes at least one chip stack attached to a processor core, wherein the at least one chip stack includes a plurality of semiconductor chips in which each semiconductor chip of the plurality semiconductor chips includes a FEOL level including at least one semiconductor device and having a frontside and a backside, a frontside BEOL structure located on the frontside of the FEOL level, and a backside BEOL structure located on the frontside of the FEOL level, in which at least one of the frontside BEOL structure or the backside BEOL structure includes an ILD material having a thermal conductivity of greater than 0.5 W/mK up to 2000 W/mK.

### BRIEF DESCRIPTION OF THE DRAWINGS

FIG. 1 is a cross sectional view of an exemplary semiconductor chip in accordance with an embodiment of the present application.

FIG. 2 is a cross sectional view of another exemplary semiconductor chip in accordance with an embodiment of the present application.

FIG. 3 is a cross sectional view of a further exemplary semiconductor chip in accordance with an embodiment of the present application.

FIG. 4 is a cross sectional view of a yet further exemplary semiconductor chip in accordance with an embodiment of the present application.

FIG. 5A is a cross sectional view of an upper portion of an exemplary semiconductor chip in accordance with an embodiment of the present application.

FIG. 5B is a top down of the upper portion of the semiconductor chip shown in FIG. 5A in accordance with one embodiment of the present application.

FIG. 5C is a top down of the upper portion of the semiconductor chip shown in FIG. 5A in accordance with one embodiment of the present application.

FIG. 6 is a cross sectional view of an upper portion of another exemplary semiconductor chip in accordance with an embodiment of the present application.

FIG. 7 is a cross sectional view of an upper portion of a further exemplary semiconductor chip in accordance with an embodiment of the present application.

FIG. 8 is a cross sectional view of multiple chips stacked, interconnected to each other and to advanced substrates or packages containing structures in accordance with an embodiment of the present application.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

Backside power delivery refers to a novel technique where power supply lines are routed on the backside of a semiconductor chip or integrated circuit (IC), rather than the traditional frontside. Backside power delivery offers several advantages, including increased logic density and improved power and performance (better signal integrity, reduced noise and improved overall chip performance). Despite the above benefits with backside power delivery, backside power delivery is thermally challenging. For example, and in traditional semiconductor structures including backside power delivery, thermal heat removal typically occurs in a vertical direction from the backside of the semiconductor structure that contains a backside power delivery (i.e., a backside BEOL) structure to the frontside that can include a heat sink located above a frontside BEOL structure. Such heat spreading/heat removal has a limit on the temperature maximum that can be removed due to the thermal resistance of the structures where limited heat removal vertically due to current materials, structures and methods. There thus is a need for providing structure including semiconductor chips and/or advanced packing technologies in which thermal heat spreading and/or heat removal is enhanced.

In the present application, structures including semiconductor chips (including chiplets and stacked chips/chiplets) and/or advanced packages are provided in which thermal heat spreading and/or thermal heat removal is improved utilizing an ILD material in at least one of the frontside BEOL structure or the backside BEOL structure that has a high thermal conductivity (i.e., greater than 0.5 W/mK up to 2000 W/mK). In some embodiments, dual purposed, mixed via stack diameters or additional metal vias stacks beyond that which is required for typical or specific signal and/or power delivery can also be used to transport heat through the structure. In some embodiments, through vias can be inserted in at least one of the frontside BEOL structure or the backside BEOL to further enhance heat transport through the structure. In yet some embodiments, high thermal conductive conductors can be used in at least one of the frontside BEOL structure or the backside BEOL or advanced package structures.

These and other aspects of the present application will be described in greater detail by referring to the drawings that accompany the present application and the discussion of those drawings herein below. Before describing the drawings of the present application however, the following terms which appear throughout this application are defined.

In the present application, a semiconductor structure is used in providing a semiconductor chip or chiplet. The semiconductor structure includes a FEOL level that includes one or more semiconductor devices present therein. The one or more semiconductor devices can include, for example, a transistor, a capacitor, a diode, and/or a resistor. In embodiments, the FEOL level includes integrated circuits (ICs). The FEOL level can also be referred to as a semiconductor device level. In some embodiments, the FEOL level can include a semiconductor substrate including at least one semiconductor material. In other embodiments, the FEOL level can be absent of a semiconductor substrate (in such an embodiments, the semiconductor substrate can be removed during backside processing of the semiconductor structure). The semiconductor structure includes a frontside and a backside. The frontside includes a side of the structure that includes the FEOL level, an optional middle-of-the-line (MOL) level, and a frontside BEOL structure. The backside of the semiconductor structure is the side of the semiconductor structure that is opposite the frontside. The backside can include a backside BEOL structure.

The semiconductor structure can be diced into a semiconductor chip or chiplet, and the diced semiconductor structure (i.e., chips or chiplets) can be used in a chip stack including a 3D chip stack.

A semiconductor material is a material that has semiconducting properties. Examples of semiconductor materials that can be used in the present application include, but are not limited to, silicon (Si), a silicon germanium (SiGe) alloy, a silicon germanium carbide (SiGeC) alloy, germanium (Ge), III/V compound semiconductors or II/VI compound semiconductors.

A frontside BEOL structure is a structure that is composed of a frontside interconnect dielectric region having frontside metal wiring embedded therein. The frontside interconnect dielectric region includes one or more interconnect dielectric layers. The one or more interconnect dielectric layers are composed of an interlayer dielectric (ILD) material such as, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that can have a dielectric constant of less than 4.0. All dielectric constants mentioned here are measured in a vacuum unless otherwise stated. Notably, the ILD materials used in providing a conventional frontside BEOL structure has a low thermal conductivity; the term “low thermal conductivity” denotes a thermal conductivity of less than 0.5 W/mK. The frontside metal wiring can be in the form of metal lines, metal vias, metal via/metal line combinations or any combinations of such conductor structures. The frontside metal wiring is composed of an electrically conductive metal or an electrically conductive metal alloy. Exemplary electrically conductive metals include, but are not limited to, Cu, W, Al, Co, or Ru. An exemplary electrically conductive metal alloy is a Cu—Al alloy. Some of the frontside metal wiring can be used for signal delivery to the one or more semiconductor devices present in the FEOL level, while other frontside metal wiring can be used as a fill area.

A MOL level includes frontside contact structures embedded in a MOL dielectric region. The frontside contact structures can be composed of an electrically conductive metal or an electrically conductive metal alloy both as exemplified above. The MOL dielectric region is composed of one of more ILD materials as defined above for the frontside BEOL structure. Notably, the ILD material used in providing a conventional MOL dielectric has a low thermal conductivity, as defined above.

A backside BEOL structure is a structure that is composed of a backside interconnect dielectric region having backside metal wiring embedded therein. The backside interconnect dielectric region includes one or more interconnect dielectric layers. The one or more interconnect dielectric layers are composed of an ILD material as mentioned above for the frontside BEOL structure. Notably, the ILD materials used in providing a conventional backside BEOL structure has a low thermal conductivity, as defined above. The backside metal wiring can be in the form of metal lines, metal vias, metal via/metal line combinations or any combinations of such conductor structures. The backside metal wiring is composed of an electrically conductive metal or an electrically conductive metal alloy, both as exemplified above. The backside metal wiring of the backside BEOL structure delivers power to the one or more semiconductor devices present in the FEOL level through the backside of the semiconductor structure.

A chiplet is a tiny IC that contains a well-defined subset of functionality. The chiplet is designed to be combined with other chiplets on an interposed in a single package. A chiplet has a smaller dimension than a semiconductor chip.

A chip stack (including a 3D chip stack) is a stack including at least one semiconductor chip or chiplet stacked on top of, and bonded to, another semiconductor chip or chiplet. The chip stacking (second over the first) can include frontside to frontside, backside to backside, frontside to backside, or backside to backside.

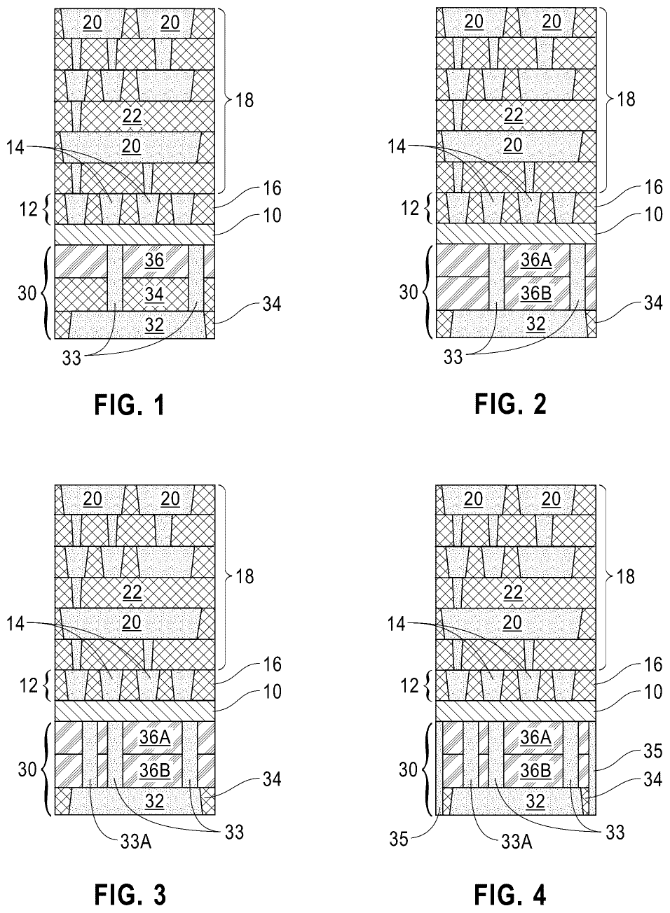

Referring first to FIG. 1, there is illustrated an exemplary semiconductor chip in accordance with an embodiment of the present application. The exemplary semiconductor chip illustrated in FIG. 1 includes a FEOL level 10 including one of more semiconductor devices as mentioned above. In some embodiments, the one or more semiconductor devices can be present on a surface of a semiconductor material as defined above. In other embodiments, no semiconductor material is present in the FEOL level 10. The FEOL level 10 includes a frontside and a backside. The FEOL level 10 can be formed utilizing FEOL processing techniques that are well known to those skilled in the art. For example, the FEOL level 10 can include nanosheet transistors that are formed utilizing any well-known nanosheet device formation process.

The structure shown in FIG. 1 further includes a MOL level 12 and a frontside BEOL structure 18 located on the frontside of the FEOL level 10, and a backside BEOL structure 30 located on the backside of the FEOL level 10. The MOL level 12 includes frontside contact structures 14 embedded in a MOL dielectric region 16. In some embodiments, the MOL level 12 can be omitted from the semiconductor chip. In the illustrated embodiment of FIG. 1, the frontside contact structures 14 are composed of an electrically conductive material (i.e., electrically conductive metal or electrically conductive material alloy as mentioned above). In the illustrated embodiment of FIG. 1, the MOL dielectric region 16 is composed of one or more ILD materials having a low thermal conductivity, as defined above. The MOL level 12 can be formed utilizing processing techniques that are well known to those skilled in the art. For example, the MOL dielectric region 16 of the MOL level 12 can be formed by deposition of one or more ILD materials. The frontside contact structures 14 can be formed by a metallization (or damascene) process.

The frontside BEOL structure 18 which is located on the frontside of the FEOL level 10 and on top of the MOL level 12 includes frontside wiring 20 embedded in a frontside interconnect dielectric region 22. In the illustrated embodiment of FIG. 1, the frontside wiring 20 is composed of an electrically conductive material (i.e., electrically conductive metal or electrically conductive material alloy as mentioned above). In the illustrated embodiment of FIG. 1, the frontside interconnect dielectric region 22 is composed of one or more ILD materials having a low thermal conductivity, as defined above. The frontside BEOL structure 18 can be formed utilizing processing techniques that are well known in the art. Notably, the frontside interconnect dielectric region 22 of the BEOL structure 18 can be formed by deposition of one or more ILD materials. The frontside wiring 20 of the BEOL structure 18 can be formed by a metallization (or damascene) process.

The backside BEOL structure 30 includes a backside interconnect dielectric region in which at least one of the ILD layers that provide the backside interconnect dielectric region is composed of an ILD material having a thermal conductivity of greater than 0.5 W/mK up to 2000 W/mK. In some embodiments, the one or more ILD materials that provide the backside dielectric region has a thermal conductivity from greater than 1 W/mK to 10 W/mK. In such embodiments, the one or more ILD materials have a layer thickness of greater than 1 micron to 40 microns or greater. Exemplary ILD materials that have a thermal conductivity from greater than 1 W/mK to 10 W/mK include, but are not limited to, silicon dioxide, SiN, SiCN, SiOCN, Al₂O₃ or glass. In further embodiments, the one or more ILD materials that provide the backside dielectric region has a thermal conductivity from greater than 10 W/mK to 500 W/mK. In such embodiments, the one or more ILD materials have a layer thickness of greater than 0.1 micron to 10 microns or greater. Exemplary ILD materials that have a thermal conductivity from greater than 10 W/mK to 500 W/mK include, but are not limited to, AlN, BeO, sapphire or diamond-like carbon. In some embodiments in which diamond like carbon is employed, the grain size of the diamond line carbon can range from a few microns up to 20 microns. In some embodiments, the high thermal conductive material is deposited at a temperature less than, or equal to, 500° C. The use of the aforementioned “high thermal conductivity” ILD materials (the term “high thermal conductivity” denotes a ILD material that has a thermal conductivity of greater than 0.5 W/mK, typically greater than 1 W/mK, and more typically greater than 10 W/mK) can provide enhanced thermal heat removal in the chip. In the illustrated embodiment of FIG. 1, backside dielectric region is composed of a first backside dielectric layer 36A (directly beneath the FEOL level 10) that is composed of a high thermal conductivity ILD material, and a lower backside dielectric layers 34 that are composed of conventional low thermal conductivity ILD materials as defined above.

The backside BEOL structure 30 illustrated in FIG. 1 further includes backside via structures 33 and a backside line structure 32 (the backside line structure 32 can be an input/output interconnect region for power distribution). The backside vias 33 connects the backside power line 32 to the one or more semiconductor devices present in the FEOL level 10. The backside vias 33 are used for power delivery and grounds and thus can be referred to as power delivery and ground vias. In illustrated embodiment of FIG. 1, the backside vias 33 can be composed of an electrically conductive material (i.e., electrically conductive metal or electrically conductive material alloy as mentioned above). In some embodiments, backside vias 33 of the backside BEOL structure 30 can be composed of an electrically conductive material having a thermal conductivity of greater than 40 W/mK. Illustrative examples of such thermally conductive conductors include, but are not limited to, Cu, Al, Ta, Mo, W, CuMo, Sn, solder, Ag, Au or alloys thereof. The backside line structure 32 is typically composed of an electrically conductive metal or electrically conductive metal alloy as mentioned above for traditional backside BEOL structures, although embodiments are contemplated in which the backside line structure 32 is composed of one or more of high thermal conductivity conductors, increased number of stacked conductors, size of stacked conductors, number or size of interconnection wires or increased thermal conductivity of dielectric layer(s). It is noted that the backside BEOL structure 30 can be referred to herein as a backside power, ground and distribution region. The backside power, ground and distribution region is a region of electrical conductors made up of vias, interconnection wires and interconnection. The power, ground and distribution region also includes dielectric materials used for electrical isolation.

Referring now to FIG. 2, there is illustrated another exemplary semiconductor chip in accordance with an embodiment of the present application. The exemplary semiconductor chip illustrated in FIG. 2 is the same as that as shown in FIG. 1 except that the backside BEOL structure 30 illustrated in FIG. 2 includes a second backside dielectric layer 36B (directly beneath the first backside dielectric layer 36A) that is composed of a high thermal conductivity ILD material. Although FIG. 2 illustrates a backside dielectric layer 34 composed of a low thermal conductivity that embeds the backside line structure 32, the present application contemplates embodiments in which the backside line structure 32 is embedded in a high thermal conductivity ILD material as defined above.

Referring now to FIG. 3, there is illustrated a further exemplary semiconductor chip in accordance with an embodiment of the present application. The exemplary semiconductor chip illustrated in FIG. 3 is the same as that as shown in FIG. 2 except that the backside BEOL structure 30 illustrated in FIG. 3 is designed to include an additional density of backside vias, backside via stacks or interconnection wires that is beyond required minimum limits needed for traditional backside power delivery. In some embodiments in which the density of at least one the backside vias, backside vias stacks, interconnection wires (number/size) is beyond limits for traditional backside power delivery and distribution or ground vias stacks or signal vias stacks or interconnection wires, the additional density of such structures can also contribute to increased thermal heat transport. In the illustrated embodiment of FIG. 3, heat transport backside via 33A is shown to represent this additional density of the backside metal vias. In some embodiments in which the density of backside metal vias is beyond minimum limits for traditional backside power delivery function, the additional density of backside metal vias is from about 10% up to 50% or even up to 75% (this range applied to the other structures mentioned above in which density is increased beyond normal operational functions. The heat transport backside vias 33A can be composed of electrically conductive materials including the high thermal conductivity conductors mentioned above. The heat transport vias 33A can be a single via or a plurality of interconnected and stacked vias.

Referring now to FIG. 4, there is illustrated a yet further exemplary semiconductor chip in accordance with an embodiment of the present application. The exemplary semiconductor chip illustrated in FIG. 4 is the same as that as shown in FIG. 3 except that the backside BEOL structure 30 illustrated in FIG. 4 is designed to contain backside heat transport through vias 35. The backside heat transport through vias 35 extend entirely through the backside BEOL structure 30. The backside heat transport through vias 35 can be composed of electrically conductive materials including the high thermal conductivity conductors mentioned above. Although not shown, the backside heat transport through vias 35 can be connected to frontside heat transport vias that are present in the frontside BEOL structure 18, the MOL level 12 and the FEOL level 10. The backside heat transport through vias stacks 35 as well as the frontside heat transport vias can be composed of one or more metal vias or metal vias stacks.

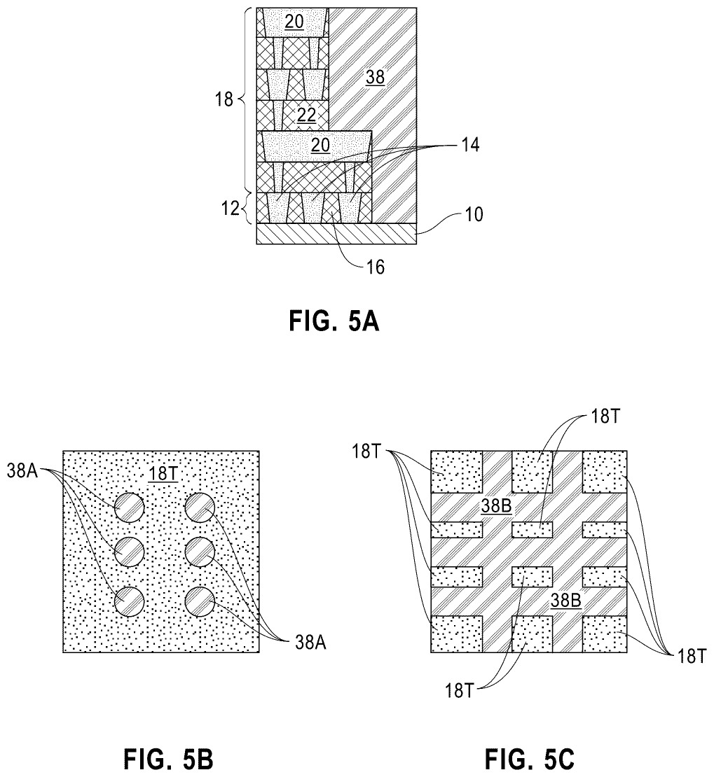

Referring now to FIG. 5A, there is illustrated an upper portion of an exemplary semiconductor chip in accordance with an embodiment of the present application. The upper portion of the semiconductor chip shown in FIG. 5A can be used in the exemplary semiconductor chips illustrated in FIGS. 1-4, or other semiconductor chips in which the backside BEOL structure 30 is a conventional backside BEOL structure. The upper portion of the semiconductor chip illustrated in FIG. 5A includes FEOL level 10, optional MOL level 12, and a frontside BEOL structure 18 as defined above and as shown, for example, in FIG. 1. In the illustrated embodiment of FIG. 5A, a portion of the frontside interconnect dielectric region 22 of the frontside BEOL structure 18 and the MOL dielectric 16 of the MOL level 12 are replaced by with a high thermal conductivity ILD material as defined above. The high thermal conductivity ILD material is provided in a shape of a high thermal conductivity dielectric pillar 38. The high thermal conductivity dielectric pillar 38 extends entirely through the frontside BEOL structure 18 and, if present the MOL level 12, and the high thermal conductivity dielectric pillar 38 has a bottommost surface that lands on the FEOL level 10. The high thermal conductivity dielectric pillar 38 enhances transparent of heat within the semiconductor chip.

In some embodiments, the high thermal conductivity dielectric pillars 38 can be arranged as discrete and isolated cylindrical high thermal conductivity dielectric pillars 38A as shown in FIG. 5A. In other embodiments, the high thermal conductivity dielectric pillars 38 can be arranged in a crisscross (intersecting) pattern to provide crisscrossed pattern or network of high thermal conductivity dielectric structures 38B as illustrated in FIG. 5C.

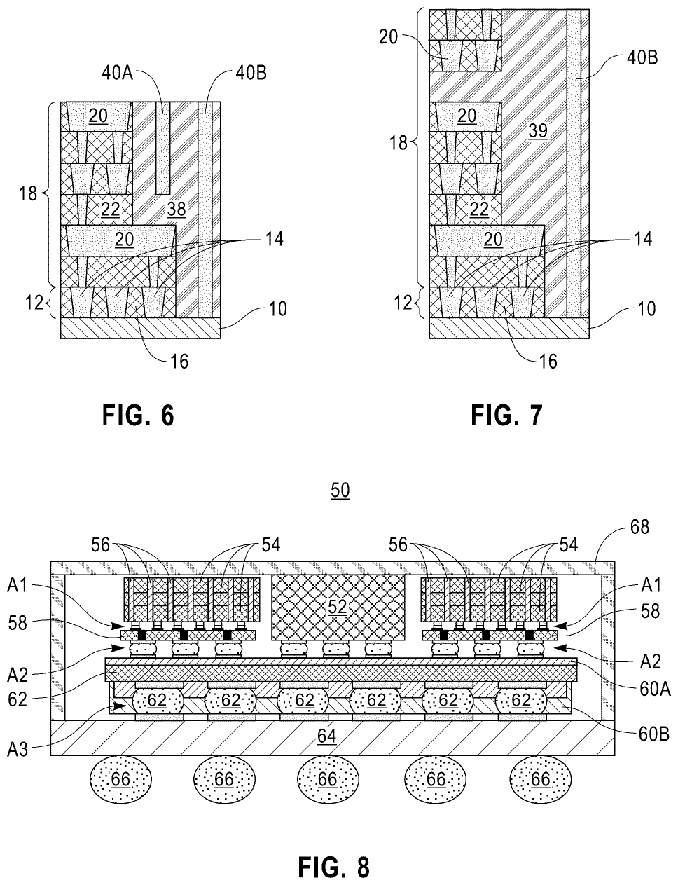

Referring now to FIG. 6, there is illustrated an upper portion of another exemplary semiconductor chip in accordance with an embodiment of the present application. The upper portion of the semiconductor chip shown in FIG. 6 can be used in the exemplary semiconductor chips illustrated in FIGS. 1-4 or other semiconductor chips in which the backside BEOL structure 30 is a conventional backside BEOL structure. The upper portion of the semiconductor chip shown in FIG. 6 in the same as that shown in FIG. 5 except that it is designed to include an inter-level frontside heat transport via 40A and a frontside heat transport via 40B in the high thermal conductivity dielectric pillar 38. While both frontside vias are shown, the present application contemplates an embodiment in which only the inter-level frontside heat transport via 40B is formed in the high thermal conductivity dielectric pillar 38, or only the frontside heat transport via 40B is formed in the high thermal conductivity dielectric pillar 38. In embodiments in which the frontside heat transport via 40B is present, the frontside heat transport via 40B typically, but not necessarily always, lands on a surface FEOL level 10; embodiments are contemplated in which the frontside heat transport via 40B extends through the FEOL level 10 and is in contact with one of the backside heat transport through vias 35. The inter-level frontside heat transport via 40A and the frontside heat transport via 40B can be composed of electrically conductive materials including the high thermal conductivity conductors mentioned above. The inter-level frontside heat transport via 40A can be used to remove heat from one of the levels within the frontside BEOL structure 18. The frontside heat transport via 40B can remove heat from at least the FEOL level 10 and entirely through the MOL level 12 and the frontside BEOL structure 18.

Referring now to FIG. 7, there is illustrated an upper portion of a further exemplary semiconductor chip in accordance with an embodiment of the present application. The upper portion of the semiconductor chip shown in FIG. 7 can be used in the exemplary semiconductor chips illustrated in FIGS. 1-4 or other semiconductor chips in which the backside BEOL structure 30 is a conventional backside BEOL structure. The upper portion of the semiconductor chip shown in FIG. 7 in the same as that shown in FIG. 6 except that no inter-level frontside heat transport via 40A is present, and the high thermal conductivity dielectric pillar 38 is designed to have a horizontal extending portion that disrupts the path of the frontside metal wiring 20. The high thermal conductivity dielectric pillar having this horizontal extending portion can be referred to herein as a frontside wiring disrupting high thermal conductivity dielectric structure 39.

It is noted that in any of the embodiment illustrated in FIGS. 1-7, the semiconductor chip can be a chiplet. Also, the various embodiments illustrated in FIGS. 1-7 can be used for provided stacked chips or stacked chiplets and/or can be used in advanced packaging technologies.

Referring now to FIG. 8, there is illustrated a structure 50 in accordance with an embodiment of the present application. In the illustrated embodiment, the structure 50 includes one or more stacked semiconductor chips or stacked chiplets on an interposer 62. Interposer 62 can include an interposer chip (i.e., an active interposer). The one or more stacked chips or stacked chiplets include at least the use of an ILD material in at least one of the frontside BEOL structure or the backside BEOL structure that has a high thermal conductivity. Notably, and in the illustrated embodiment, there is shown a pair of spaced apart stacked chips 54. In some embodiments, only one first stacked chip 54 can be present. The stacked chips 54 include a plurality of semiconductor chips in accordance with one of the embodiments of the present application. In some embodiments, each stacked chip 54 can have high thermal conductivity dielectric pillars that are shaped as stripes or structures (as an example, the second stacked chips include a thermal conductivity dielectric striped structure 56). The high thermal conductivity dielectric pillars or structures or electrical and thermal conductor materials, pillars, vias, via stacks, lines or structures of FIG. 8 are composed of at least one of an ILD material having a high thermal conductivity, a structure containing increased thermal conductivity for the electrical conductors or combinations thereof as defined above.

Also shown is a chip hub 52 (or control chip) that is located laterally adjacent to at least one of the second stacked chip stacks 54, and a core processor chip 58 (the core process chip can be designed to have enhanced thermal heat spreading and thermal heat removal provided by any or all of the various embodiments of the present application). The chip hub 52 is used in the present application as a GPU, ASIC accelerator, CPU, Control chip, Switch Chip or combinations of functions thereof. In the some embodiments, a lid 68 is present. The lid 68 is composed of a thermal conductive material such as, for example, Cu Ni plated Cu, Al, or alternate material. The lid 68 is attached to the stacked chips 54 and the chip hub 52. A portion of the lid 68 can also be attached to a chip integration base substrate 64. The lid 68 encases the stacked chips 54, the chip hub 52, the core processor chip 58, the interposer 62 and chip integration base substrate 64 in which the enhanced horizontal and vertical thermal heat spreading and heat removal structures described in the chips and chiplets illustrated in FIGS. 1-7 can also be captured in one or more of the chips, chip stacks, the interposer, advanced packaging, base substrate and can provide an additional heat spreading and heat removal path from the circuits either vertically upward to the lid or heat sink or downward, horizontally and then vertically to the lid at one or more connections to the lid such as but not limited to the perimeter of the interposer or substrate by means of dielectric or conductor or dielectric and conductor thermal paths.

Each stacked chip 54 is attached to core processor chip 58 by a first attachment means A1. The first attachment means Al can include bond pads and solder balls. Each core processor chip 58 and the chip hub 52 are attached to structure that includes chip to chip interconnect PHY such as industry standard BOW, UCIe, HBM or alternate PHY and use of solder interconnections, micro-solder or micro-pillar solder interconnections, Cu-Hybrid bonding or Cu—Cu bonding or combinations of one or more PHY and one or more electrical and thermal interconnections. Enhanced interposer or chip interposer thermal connection such as by example shown where a high thermal conductors on either side (top, bottom or top and bottom) of the interposer shown as a first high thermal conductivity ILD layer 60A and a second high thermal conductivity ILD layer 60B. Notably, each core processor chip 58 and the chip hub 52 is attached to the first high thermal conductivity ILD layer 60A. The attachment of each one or multi-core processor chip 58 and the chip hub 52 to the structure including the universal chip interconnections described above and linked to base substrate which can also contain a top, middle, bottom or combinations thereof along with continuous thermal conduction paths from heat source to heat sink or lid vertically up or vertically down, horizontally and vertically up to lid edge or additional paths from interposer or substrate to one or more lid thermal paths includes a second attachment means A2 or other paths not shown. The second attachment means A2 can include bond pads and solder balls.

The universal chip interconnect 62 is attached to the chip integration substrate 64 (typically an organic material) by a third attachment means A3. The third attachment means A3 can include bond pads and solder balls Note that the third attachment means A3 passes through the second high thermal conductivity ILD layer 60B. In some embodiments, and as shown in FIG. 8, an underfill material layer 62 can be used to encase each of the solder balls present in A3 and to fill in any gap that is located between the chip integration base substrate 6464 and the second high thermal conductivity ILD layer 60B. The chip integration base substrate 64 can also include solder balls 66 which can be used for attachment of the chip integration base substrate 64 to a packaging substrate (not shown).

The chip stack containing structure 50 illustrated in FIG. 8 has enhanced thermal heat removal at the chip level due to the presence ILD materials in at least one of the frontside BEOL structure or the backside BEOL structure of the stacked chips that have high thermal conductivity. Further heat removal at the chip level can be provided by the high thermal conductivity dielectric pillar stripes. The chip stack containing structure 50 illustrated in FIG. 8 has enhanced thermal heat removal at the universal chip interconnect level by the presence of the first high thermal conductivity ILD layer 60A and the second high thermal conductivity ILD layer 60B that sandwich the universal chip interconnections such as solder balls, micro-BGA interconnections, and then continuing through an enhanced base substrate having such as with an enhanced thermal heat spreader on top of chip integration base substrate 64 going to the lid edge with thermal connection such as solder interconnection or thin thermal adhesive and then up to lid edge and heat sink.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A structure comprising:
a front-end-of-the-line (FEOL) level comprising at least one semiconductor device and having a frontside and a backside;
a frontside back-end-of-the-line (BEOL) structure located on the frontside of the FEOL level; and
a backside BEOL structure located on the frontside of the FEOL level, wherein at least one of the frontside BEOL structure or the backside BEOL structure comprises an interlayer dielectric (ILD) material having a thermal conductivity of greater than 0.5 W/mK up to 2000 W/mK.

2. The structure of claim 1, wherein the backside BEOL structure comprises the ILD material, and the ILD material is present in at least one backside ILD layer of the backside BEOL structure.

3. The structure of claim 2, wherein the backside BEOL structure comprises a power delivery via and a heat transport via.

4. The structure of claim 3, wherein the backside BEOL structure further comprises a backside heat transport through via.

5. The structure of claim 2, wherein the backside BEOL structure comprises a backside heat transport through via.

6. The structure of claim 1, wherein the frontside BEOL structure comprises the ILD material.

7. The structure of claim 6, wherein the ILD material provides a high thermal conductivity dielectric pillar that extends through the frontside BEOL structure.

8. The structure of claim 7, further comprising at least one of an inter-level frontside heat transport via or a frontside heat transport via present in the high thermal conductivity dielectric pillar.

9. The structure of claim 7, wherein the high thermal conductivity dielectric is a cylindrical high thermal conductivity dielectric pillar, a cross-crossed high thermal conductivity dielectric structure or a stripped shaped high thermal conductivity dielectric structure.

10. The structure of claim 6, wherein the ILD material provides a frontside wiring disrupting high thermal conductivity dielectric structure that has a horizontal portion that disrupts frontside wiring present in the frontside BEOL structure.

11. The structure of claim 10, further comprising a frontside heat transport via present in the frontside wiring disrupting high thermal conductivity dielectric structure.

12. The structure of claim 1, wherein the ILD material is present in both the backside BEOL structure and the frontside BEOL structure.

13. The structure of claim 12, wherein the ILD material in the backside BEOL structure is present in at least one backside ILD layer of the backside BEOL structure, and the ILD material the frontside BEOL structure provides a high thermal conductivity dielectric pillar that extends through the frontside BEOL structure or a frontside wiring disrupting high thermal conductivity dielectric structure that has a horizontal portion that disrupts a frontside wiring present in the frontside BEOL structure.

14. The structure of claim 13, wherein the backside BEOL structure further comprises a power delivery via and a heat transport via, a backside heat transport through via or a combination of a power delivery via, a heat transport via and a backside heat transport through via.

15. The structure of claim 13, wherein the frontside BEOL structure further comprises at least one of an inter-level frontside heat transport via or a frontside heat transport via present in the high thermal conductivity dielectric pillar.

16. The structure of claim 13, wherein the frontside BEOL structure further comprises a frontside heat transport via present in the frontside wiring disrupting high thermal conductivity dielectric pillar.

17. A chip stack containing structure comprising:
at least one chip stack attached to a processor core, wherein the at least one chip stack comprises a plurality of semiconductor chips in which each semiconductor chip of the plurality semiconductor chips comprises a front-end-of-the-line (FEOL) level comprising at least one semiconductor device and having a frontside and a backside, a frontside back-end-of-the-line (BEOL) structure located on the frontside of the FEOL level, and a backside BEOL structure located on the frontside of the FEOL level, wherein at least one of the frontside BEOL structure or the backside BEOL structure comprises an interlayer dielectric (ILD) material having a thermal conductivity of greater than 0.5 W/mK up to 2000 W/mK.

18. The chip stack containing structure of claim 17, further comprises a universal chip interconnect structure sandwiched between a first high thermal conductivity ILD layer and a second high thermal conductivity ILD layer, wherein the first high thermal conductivity ILD layer is attached to the processor core.

19. The chip stack containing structure of claim 18, wherein the universal chip interconnect structure is attached to a chip integration substrate.

20. The chip stack containing structure of claim 19, further comprising a lid attached to the at least one chip stack and to the chip integration substrate.
